(19) United States
(12) Patent Application Publication
(10) Pub. No.: US 2026/0223470 A1
(43) Pub. Date: Jul. 30, 2026

(54) IMAGE SENSOR

(71) Applicant: Samsung Electronics Co., Ltd., Suwon-si (KR)

(72) Inventors: Byunghong Chung, Suwon-si (KR); Seokjin Kwon, Suwon-si (KR); Sung In Kim, Suwon-si (KR); Jinhyung Kim, Suwon-si (KR); Changrok Moon, Suwon-si (KR); Sunwook Park, Suwon-si (KR); Inyong Park, Suwon-si (KR); Yangjae Yun, Suwon-si (KR); Beomsuk Lee, Suwon-si (KR); In Sung Joe, Suwon-si (KR)

(21) Appl. No.: 19/450,129

(22) Filed: Jan. 15, 2026

(30) Foreign Application Priority Data
Jan. 24, 2025 (KR) 10-2025-0011566

(51) Int. Cl. H10F 39/00

(52) U.S. Cl. CPC H10F 39/806; H10F 39/8053; H10F 39/807

(57) ABSTRACT

An image sensor includes a substrate including a plurality of photoelectric convertors and a prism structure on the substrate. The prism structure includes a mold pattern and a plurality of refractive structures provided in the mold pattern. Each refractive structure of the plurality of refractive structures includes a first portion and a second portion on the first portion. The second portion has a first width in a first direction parallel to an upper surface of the substrate. The first width increases in a direction away from the upper surface of the substrate.

### CROSS-REFERENCE TO RELATED APPLICATIONS

This application claims priority under 35 U.S.C. § 119 to Korean Patent Application No. 10-2025-0011566 filed on Jan. 24, 2025, in the Korean Intellectual Property Office, the contents of which are herein incorporated by reference in their entirety.

### BACKGROUND

An image sensor is a semiconductor device that transforms optical images into electrical signals. The image sensor may be classified into a charge coupled device (CCD) type or a complementary metal oxide semiconductor (CMOS) type. A CMOS image sensor (CIS) refers to a CMOS type image sensor. The CIS may include a plurality of two-dimensionally arranged pixels. Each of the pixels includes a photodiode (PD). The photodiode serves to transform an incident light into an electrical signal.

### SUMMARY

Aspects of this disclosure provide an image sensor providing a clearer image.

The problems to be solved by the present disclosure are not limited to the problems mentioned above, and other problems not mentioned may be clearly understood by a person having ordinary skill in the art from the description below.

An image sensor according to some implementations of the present disclosure may include a substrate including a plurality of photoelectric convertors and a prism structure on the substrate, wherein the prism structure includes a mold pattern and a refractive structure provided in the mold pattern, the refractive structure includes a first portion and a second portion on the first portion, the second portion has a first width in a first direction parallel to an upper surface of the substrate, and the first width increases in a direction away from the upper surface of the substrate.

An image sensor according to some implementations of the present disclosure may include a substrate including a plurality of photoelectric convertors, a separation structure in the substrate to separate the plurality of photoelectric convertors, and a prism structure on an upper surface of the substrate, wherein the prism structure includes a mold pattern and a refractive structure in the mold pattern, the refractive structure includes a first portion and a second portion on the first portion, an angle formed by an upper surface of the first portion and a side surface of the second portion is an obtuse angle, and the second portion has a trapezoidal shape when viewed in cross-sectional view.

An image sensor according to some implementations of the present disclosure may include a substrate having a first surface and a second surface facing each other and including a plurality of photoelectric convertors, a separation structure in the substrate and separating the plurality of photoelectric convertors, a color filter on the second surface of the substrate, and a first prism structure on the color filter, wherein the first prism structure includes a first mold pattern and a plurality of first refractive structures in the first mold pattern, a refractive index of the first refractive structures is 1.2 to 2.5, each of the first refractive structures includes a first portion and a second portion on the first portion, the first portion has a first width in a first direction parallel to the second surface, the second portion has a second width in the first direction, the first width is constant regardless of a height of the first portion, the second width increases in a direction away from the second surface, and a height of the second portion is 10% to 70% of a height of the first mold pattern.

A method of manufacturing an image sensor according to some implementations of the present disclosure may include preparing a substrate, forming photoelectric convertor in the substrate, and forming a prism structure on the substrate, wherein the forming of the prism structure includes forming a mold layer on the substrate, etching the mold layer to form a plurality of holes, and forming a plurality of refractive structures filling the plurality of holes, and the etching of the mold layer to form the plurality of holes includes forming a width of each of upper portions of the holes to increase in a direction away from an upper surface of the substrate.

According to some implementations, the forming of the width of each of the upper portions of the holes to increase in the direction away from the upper surface of the substrate may include performing a chamfering process on an upper portion of the mold layer.

According to some implementations, the method further comprises forming a hard mask pattern on the mold layer before the etching of the mold layer to form the plurality of holes, wherein the hard mask pattern includes at least one of titanium nitride, tantalum nitride, titanium oxide, hafnium oxide, zirconium oxide, tungsten, titanium, tantalum, molybdenum, chromium, hafnium, or ruthenium.

According to some implementations, the refractive structures may include the same material as that of the hard mask pattern.

According to some implementations, the forming of the refractive structures may include performing a chemical vapor deposition process and an atomic layer deposition process.

According to some implementations, the method further comprises performing a planarization process on the refractive structures.

### BRIEF DESCRIPTION OF THE DRAWINGS

Example implementations will be more clearly understood from the following brief description taken in conjunction with the accompanying drawings. The accompanying drawings represent non-limiting, example implementations as described herein.

FIG. 1 is a plan view of an image sensor according to some implementations.

FIG. 2 is a cross-sectional view taken along line A-A′ of FIG. 1.

FIG. 3A is an enlarged view of portion ‘CU1’ of FIG. 2.

FIG. 3B is an enlarged view of portion ‘CU2’ of FIG. 2.

FIG. 4 is an enlarged view of portion ‘CU1’ of FIG. 2 according to some implementations.

FIGS. 5, 6, 7, 8, 9, 10, 11, 12, 13, and 14 are cross-sectional views illustrating a manufacturing process of an image sensor according to some implementations. FIG. 10 is an enlarged view of portion ‘CU3’ of FIG. 9. FIG. 12 is an enlarged view of portion ‘CU4’ of FIG. 11. FIG. 14 is an enlarged view of portion ‘CU5’ of FIG. 13.

FIG. 15 is a cross-sectional view of an image sensor according to some implementations.

### DETAILED DESCRIPTION

Hereinafter, the present disclosure will be described in detail by describing implementations with reference to the attached drawings.

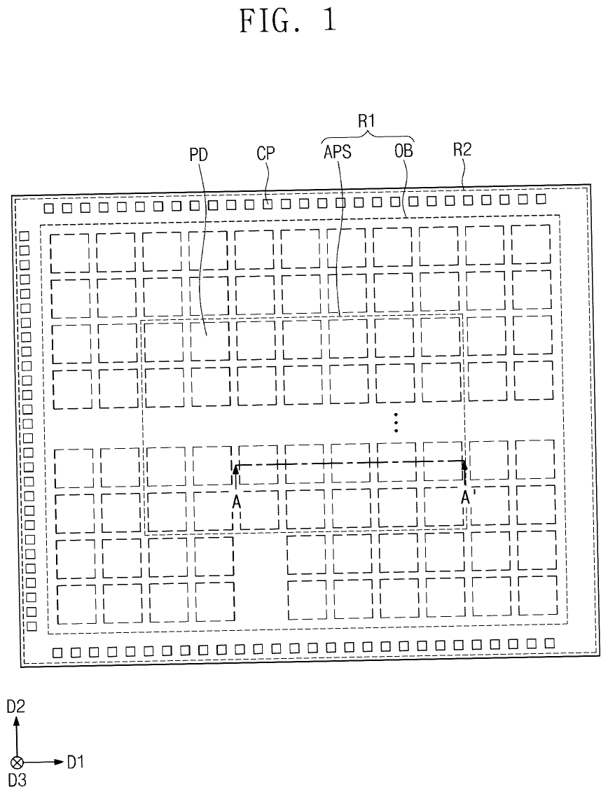

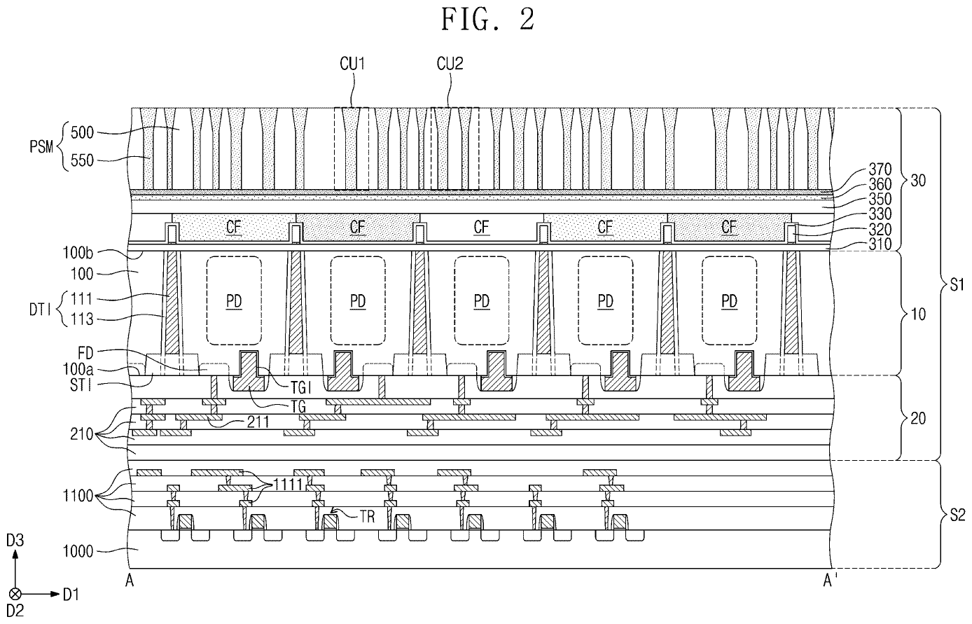

FIG. 1 is a plan view of an image sensor according to some implementations. FIG. 2 is a cross-sectional view taken along line A-A′ of FIG. 1.

Referring to FIGS. 1 and 2, an image sensor according to some implementations may include a first chip S1 and a second chip S2. In some implementations, the concept of individual chips may be defined as stacked structures formed from different semiconductor wafers. Although boundaries of individual chips may not be clearly distinguished depending on the bonding type and bonding material between the chips, even in the case of such a stacked structure, the concept of individual chips formed from different semiconductor wafers is not excluded.

The first chip S1 may be a sensor chip. The second chip S2 may be a logic chip. The first chip S1 may, for example, perform an image sensing function. The second chip S2 may include, for example, circuits for driving the first chip S1 or storing electrical signals generated from the first chip S1.

The first chip S1 may include a substrate 100. The substrate 100 may include a first surface 100a and a second surface 100b that face each other. Light may be incident into the substrate 100 through the second surface 100b. In some implementations, the first surface 100a may correspond to a lower surface of the substrate 100. The second surface 100b may correspond to an upper surface of the substrate 100. The substrate 100 may be a single crystal wafer or an epitaxial layer or a silicon on insulator (SOI) substrate including silicon and/or germanium.

In some implementations, a first direction D1 is defined as a direction parallel to the first surface 100a of the substrate 100. A second direction D2 is defined as a direction parallel to the first surface 100a of the substrate 100 and perpendicular to the first direction D1. A third direction D3 is defined as a direction perpendicular to the first surface 100a of the substrate 100.

The first chip S1 may include an array region R1 and a pad region R2. The array region R1 may include a plurality of photoelectric convertors PD arranged two-dimensionally in the first direction D1 and the second direction D2.

The array region R1 may include a sensing region APS and an optical black region OB. When viewed in a plan view, the optical black region OB may surround the sensing region APS. The optical black region OB may include portions where light is not incident.

The pad region R2 may have a plurality of conductive pads CP disposed to input/output control signals and photoelectric signals. When viewed in a plan view, the pad region R2 may surround the array region R1.

Referring again to FIG. 2, the image sensor according to some implementations may include a photoelectric conversion layer 10, a wiring layer 20, and a light transmitting layer 30 when viewed in a side view. The photoelectric conversion layer 10 may be disposed between the wiring layer 20 and the light transmitting layer 30. Light incident from the outside may be converted into an electrical signal in the photoelectric conversion layer 10. The photoelectric conversion layer 10 may include a substrate 100 and separation structures DTI disposed inside the substrate 100 and photoelectric convertors PD.

The substrate 100 may be doped with a first impurity to have a first conductivity type. The first impurity may be, for example, boron. The first conductivity type may be, for example, P type.

The photoelectric convertors PD may be disposed in the substrate 100. The photoelectric convertor PD may be doped with a second impurity to have a second conductivity type different from the first conductivity type. The second impurity may be, for example, phosphorus or arsenic. The second conductivity type may be, for example, N type. In this case, the N type region of the photoelectric convertor PD described above may form a PN junction with the P type region of the substrate 100 to form a photodiode, and when light is incident, electron-hole pairs may be generated by the PN junction. The electrons generated by the process may move to the photoelectric convertor PD.

A device isolation portion STI may be disposed on a first surface 100a of a substrate 100. The device isolation portion STI may include at least one of silicon oxide, silicon nitride, and silicon oxynitride.

The separation structure DTI may be disposed in the substrate 100 to separate photoelectric convertors PD from each other. The separation structure DTI may penetrate the substrate 100. A width of the separation structure DTI may become narrow from the first surface 100a to the second surface 100b.

The separation structure DTI may include a first separation pattern 111 and a second separation pattern 113. The first separation pattern 111 may be disposed to be spaced apart in the substrate 100. The first separation pattern 111 may include a conductive material having a different refractive index from that of the substrate 100. The first separation pattern 111 may include, for example, polysilicon or metal doped with impurities.

The second separation pattern 113 may be interposed between the first separation pattern 111 and the substrate 100. The second separation pattern 113 may include an insulating material having a different refractive index from that of the substrate 100. For example, the second separation pattern 113 may include silicon oxide.

A negative bias voltage may be applied to the first separation pattern 111. The first separation pattern 111 may serve as a common bias line. Accordingly, holes that are capable of existing on a surface of the substrate 100 in contact with the separation structure DTI may be captured, thereby improving dark current characteristics.

Although it is illustrated that there is a boundary between the device isolation portion STI and the separation structure DTI, the boundary may not be distinguished between the device isolation portion STI and the separation structure DTI. For example, there may be no interface between the device isolation portion STI and the second separation pattern 113. In this case, the device isolation portion STI and the second separation pattern 113 may be formed of the same material.

A transfer gate electrode TG may be disposed on the first surface 100a of the substrate 100. For example, a portion of the transfer gate electrode TG may be provided in the substrate 100. The remaining portion of the transfer gate electrode TG may be provided on the first surface 100a. That is, a portion of the transfer gate electrode TG may extend into the substrate 100. A gate insulating layer TGI may be interposed between the transfer gate electrode TG and the substrate 100.

A floating diffusion region FD may be disposed adjacent to the transfer gate electrode TG in the substrate 100. The floating diffusion region FD may be doped with a second impurity to have a second conductivity type. When a voltage is applied to the transfer gate electrode TG, electrons may move to the floating diffusion region FD.

Although not illustrated, in addition to the photoelectric convertor PD and the transfer gate electrode TG, a gate electrode of a reset transistor, a gate electrode of a source follower transistor, and a gate electrode of a selection transistor may be provided on the first surface 100a of the substrate 100. The photoelectric convertor PD and the transistors may constitute a unit pixel.

The wiring layer 20 may be disposed on the first surface 100a of the substrate 100. The wiring layer 20 may include a plurality of interlayer insulating layers 210 and wiring patterns 211. Specifically, a plurality of interlayer insulating layers 210 may be provided on the first surface 100a of the substrate 100. The interlayer insulating layer 210 may include at least one of silicon oxide and silicon nitride. The wiring patterns 211 may be provided in the interlayer insulating layer 210. The wiring patterns 211 may be electrically connected to the substrate 100. That is, the wiring patterns 211 may be electrically connected to the floating diffusion region FD and the photoelectric convertor PD.

The light transmitting layer 30 may be disposed on a second surface 100b of the substrate 100. The light transmitting layer 30 may include a fixed charge layer 310, a grid 320, a first protective layer 330, a color filter CF, a planarization layer 350, a second protective layer 360, an etching stop layer 370, and a prism structure PSM. The light transmitting layer 30 may filter light incident from the outside and provide the light to the photoelectric conversion layer 10.

The fixed charge layer 310 may be in contact with the second surface 100b of the substrate 100. The fixed charge layer 310 may be formed of a metal oxide layer or a metal fluoride layer containing an amount of oxygen or fluorine less than the stoichiometric ratio. As a result, the fixed charge layer 310 may have a negative fixed charge. The fixed charge layer 310 may be formed of a metal oxide or a metal fluoride containing at least one metal selected from hafnium (Hf), zirconium (Zr), aluminum (Al), tantalum (Ta), titanium (Ti), yttrium (Y), and lanthanum (La). Hole accumulation may occur around the fixed charge layer 310. As a result, occurrence of dark current and white spots may be effectively reduced. Preferably, the fixed charge layer 310 may include at least one of aluminum oxide and hafnium oxide.

The grids 320 may be disposed on the fixed charge layer 310. Each of the grids 320 may include a light-shielding pattern and/or a low-refractive pattern. In some implementations, the light-shielding pattern may include a metal such as titanium (Ti), tantalum (Ta), or tungsten (W). The low-refractive pattern may be made of a material having a lower refractive index than that of the light-shielding pattern. The low-refractive pattern may be made of an organic material and may have a refractive index of about 1.1 to 1.3.

The first protective layer 330 may cover the fixed charge layer 310 and the grid 320. The first protective layer 330 may include at least one of aluminum oxide and silicon oxide.

The color filter CF may be disposed on the fixed charge layer 310. The color filter CF may include a photoresist material to which a dye or pigment is added. According to some implementations, adjacent color filters CF may have different colors and may be configured in a Bayer pattern.

The planarization layer 350 may be disposed on the color filter CF. The planarization layer 350 may include, for example, an organic material. The second protective layer 360 may be disposed on the planarization layer 350. The second protective layer 360 may include, for example, silicon oxide. The etching stop layer 370 may be disposed on the second protective layer 360. The etching stop layer 370 may include, for example, aluminum oxide. The planarization layer 350, the second protective layer 360, and the etching stop layer 370 may extend in the first direction D1.

The prism structure PSM may be disposed on an etching stop layer 370. The prism structure PSM may include a mold pattern 500 and a plurality of refractive structures 550 provided in the mold pattern 500. For example, the refractive index of the mold pattern 500 may be 2.0 or less. For example, a refractive index of the refractive structure 550 may be 1.2 to 2.5. Light may be separated into red light, green light, and blue light through the refractive structures 550 and may travel into the substrate 100. A plurality of refractive structures 550 may be provided and may be spaced apart in the first direction D1 and/or the second direction D2.

The mold pattern 500 may include, for example, silicon oxide. The refractive structures 550 may include a high refractive material. The refractive structures 550 may include, for example, at least one of titanium nitride, tantalum nitride, titanium oxide, hafnium oxide, zirconium oxide, tungsten, titanium, tantalum, molybdenum, chromium, hafnium, or ruthenium. A detailed description of the prism structure PSM will be described later.

The second chip S2 may be provided below the first chip S1. The second chip S2 may include a logic substrate 1000, logic circuits TR, wiring structures 1111 connected to the logic circuits TR, and logic interlayer insulating layers 1100. The uppermost layer of the logic interlayer insulating layers 1100 may be bonded to the wiring layer 20 of the first chip S1. Although not illustrated, the second chip S2 may be electrically connected to the first chip S1 through a penetration electrode or a bonding between bonding pads.

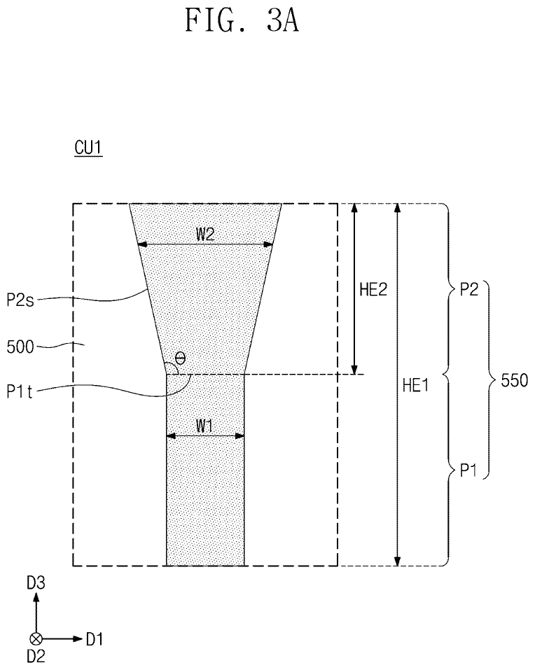

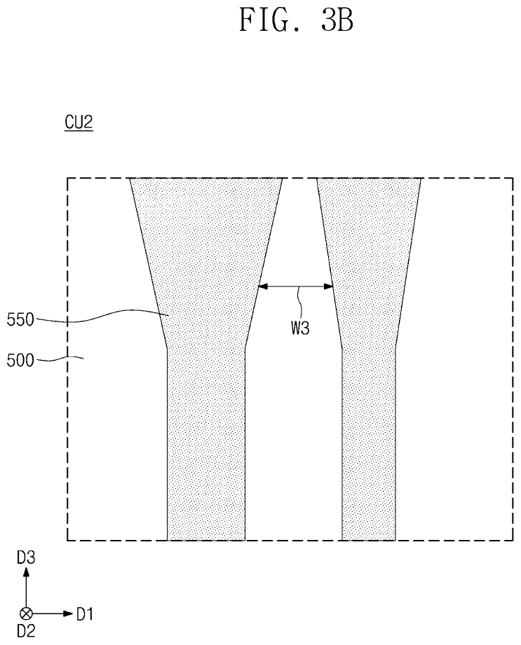

FIG. 3A is an enlarged view of portion ‘CU1’ of FIG. 2. FIG. 3B is an enlarged view of portion ‘CU2’ of FIG. 2.

Referring to FIGS. 2 to 3B, the prism structure PSM according to some implementations may include the mold pattern 500 and the plurality of refractive structures 550 provided in the mold pattern 500.

The refractive structure 550 may include a first portion P1 and a second portion P2 on the first portion P1. The first portion P1 may correspond to a lower portion of the refractive structure 550. The second portion P2 may correspond to an upper portion of the refractive structure 550.

The first portion P1 may extend in the third direction D3. When viewed in a cross-sectional view, the first portion P1 may have a rectangular shape. When viewed in a cross-sectional view, the second portion P2 may have a trapezoidal shape.

The first portion P1 may have a first width W1 in the first direction D1. The second portion P2 may have a second width W2 in the first direction D1. The first width W1 may be constant regardless of a height of the first portion. The second width W2 may increase in a direction away from the second surface 100b of the substrate 100. The second width W2 may be greater than the first width W1. For example, the second width W2 may be 1.1 to 1.5 times greater than the first width W1. As shown in FIG. 3B, a width W3 in the first direction D1 of the upper portion of the mold pattern 500 disposed between adjacent refractive structures 550 may decrease in a direction away from the second surface 100b of the substrate 100.

An angle θ formed by an upper surface P1t of the first portion P1 and a side surface P2s of the second portion P2 may be an obtuse angle. For example, the angle θ formed by the upper surface P1t of the first portion P1 and the side surface P2s of the second portion P2 may be 91 degrees to 135 degrees. For example, the angle θ formed by the upper surface P1t of the first portion P1 and the side surface P2s of the second portion P2 may be 135 degrees.

The mold pattern 500 may have a first height HE1 in the third direction D3. The second portion P2 may have a second height HE2 in the third direction D3. The second height HE2 may be 10% to 70% of the first height HE1. The first height HE1 may be, for example, 0.2 μm to 1.5 μm.

Referring to FIGS. 2 and 3B, widths of the plurality of refractive structures 550 in the first direction D1 may be different or the same. Distances between adjacent refractive structures 550 in the first direction D1 may be different or the same. For example, an arrangement and widths of the refractive structures 550 disposed on one color filter CF may be different from an arrangement and widths of the refractive structures 550 disposed on the adjacent color filter CF.

Accordingly, when light passes through the plurality of refractive structures 550, a phase difference occurs, and the light may be separated and focused into light having a specific wavelength range. For example, when light passes through the refractive structures 550, the light may be separated and focused into red light, green light, and blue light. Thereafter, the separated light may be moved to a color filter CF of a corresponding color.

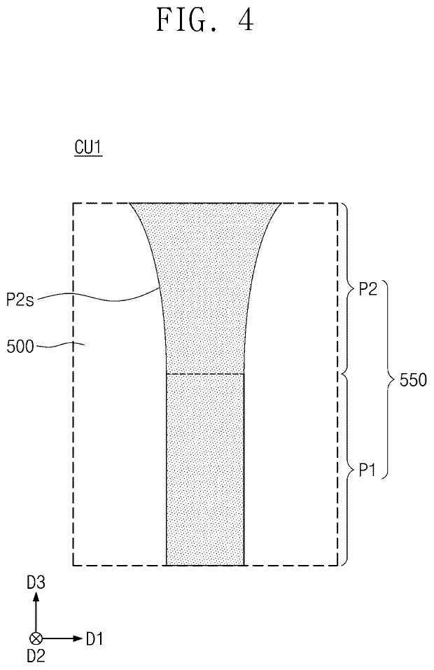

FIG. 4 is an enlarged view of portion ‘CU1’ of FIG. 2 according to some implementations.

Referring to FIG. 4, side surface P2s of the second portion P2 may have a rounded shape in a cross-sectional view. Unlike FIG. 3A, the side surface P2s of the second portion P2 may have a curved shape rather than a straight shape. Other structural features may be substantially the same as those described in FIG. 3A.

An image sensor according to some implementations may include the prism structure on the substrate. The prism structure may include the mold pattern and the refractive structures disposed in the mold pattern and including the high refractive material. In this case, the refractive structure may be formed of the high refractive material without a seam or void, and the width of the upper portion of the refractive structure may increase in the direction away from the substrate. As a result, light separation phenomenon of the prism structure is improved, and an image sensor providing a clear image may be provided.

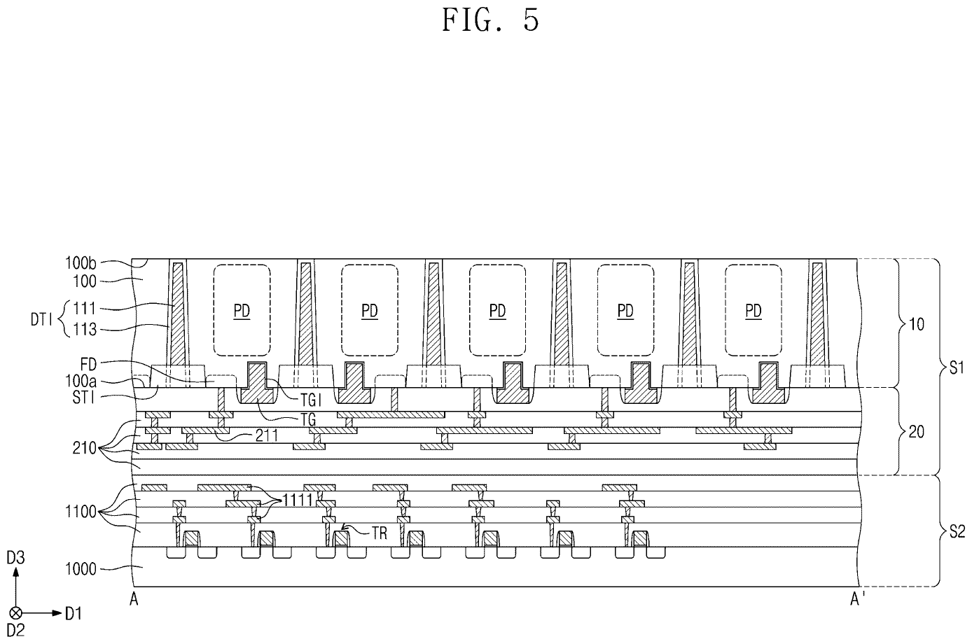

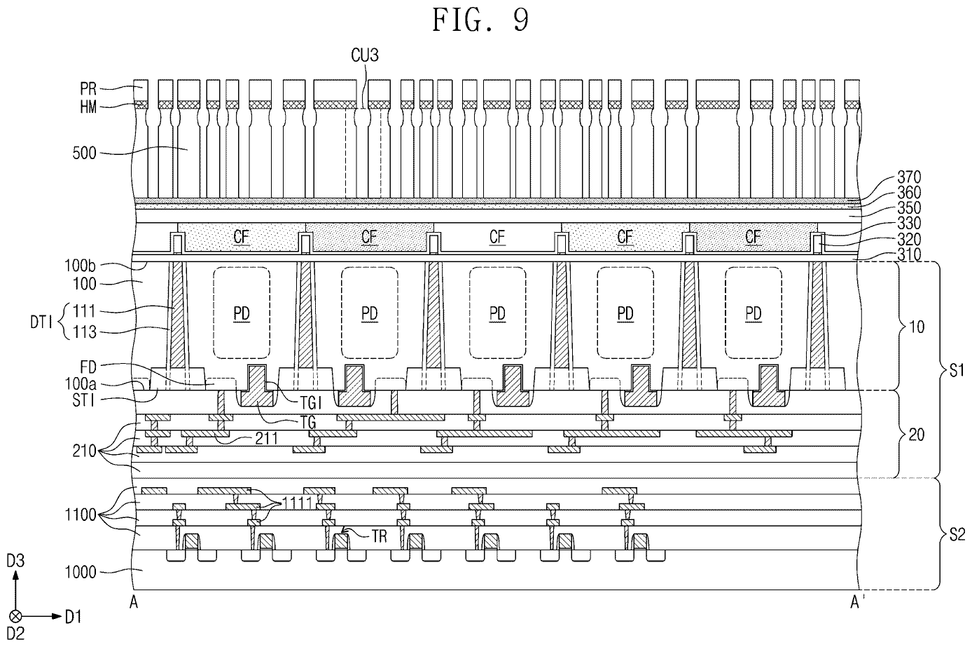

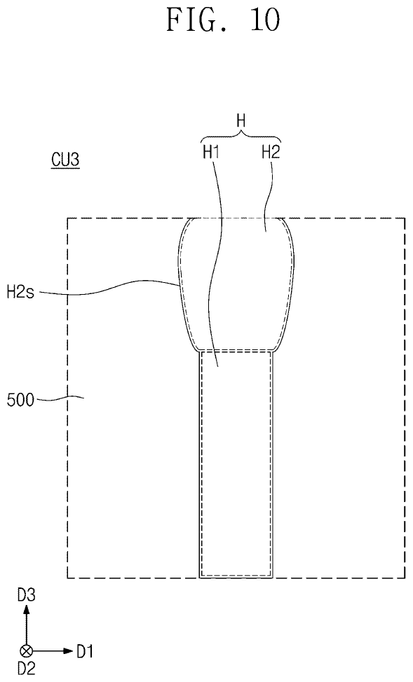

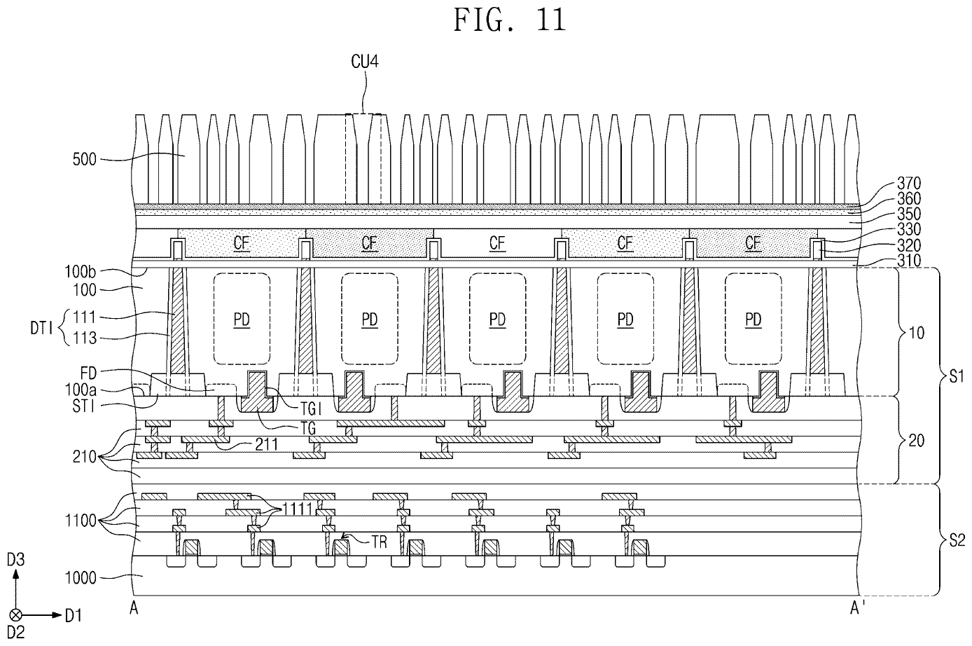

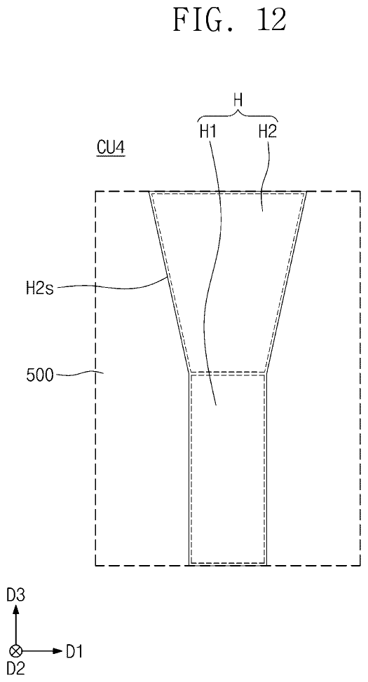

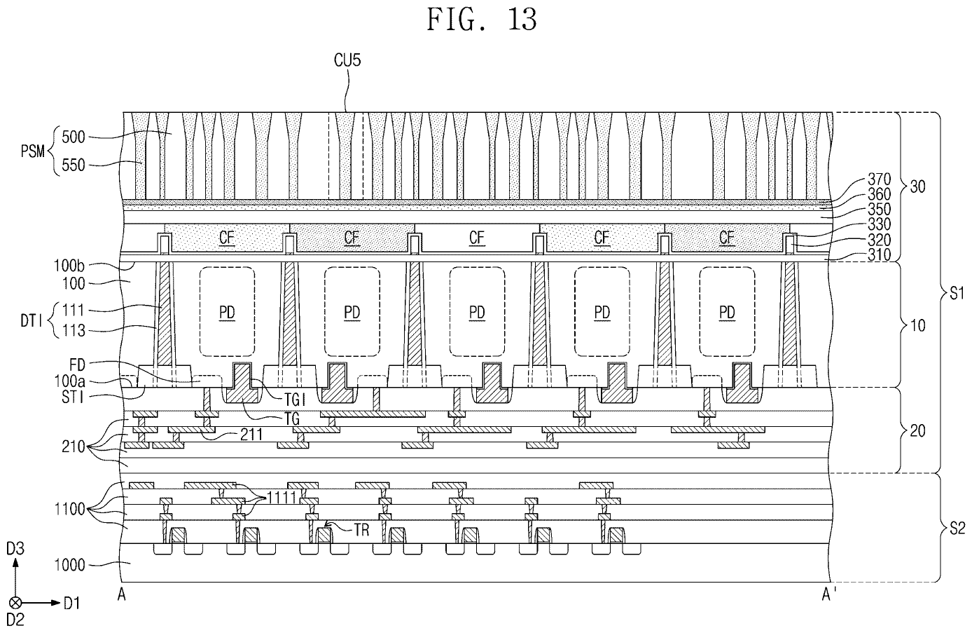

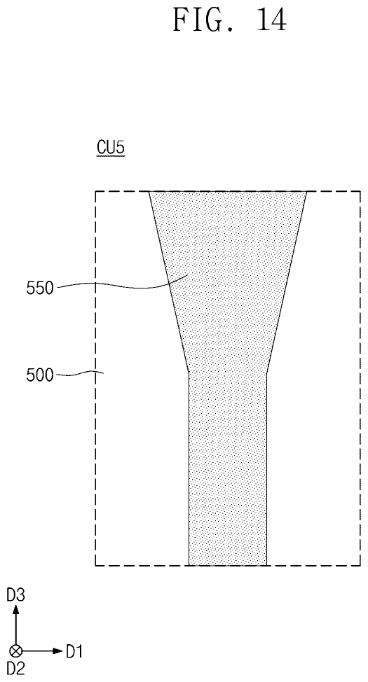

FIGS. 5, 6, 7, 8, 9, 10, 11, 12, 13, and 14 are cross-sectional views illustrating a manufacturing process of an image sensor according to some implementations. Specifically, FIG. 10 is an enlarged view of portion ‘CU3’ of FIG. 9. FIG. 12 is an enlarged view of portion ‘CU4’ of FIG. 11. FIG. 14 is an enlarged view of portion ‘CU5’ of FIG. 13.

Referring to FIG. 5, a substrate 100 having a first surface 100a and a second surface 100b facing each other may be provided. The substrate 100 may have a first conductivity type (e.g., a P type). A device isolation portion STI may be formed on the first surface 100a of the substrate 100. The device isolation portion STI may be formed, for example, through a shallow trench isolation process.

A separation structure DTI may be formed by penetrating the substrate 100. The separation structure DTI may include a first separation pattern 111 and a second separation pattern 113.

Photoelectric convertors PD may be formed in the substrate 100. A transfer gate electrode TG and a floating diffusion region FD may be formed on a first surface 100a of the substrate 100. A portion of the transfer gate electrode TG may extend into the substrate 100. As the photoelectric convertors PD, the transfer gate electrode TG, and the floating diffusion region FD are formed, a photoelectric conversion layer 10 may be formed.

A wiring layer 20 may be formed below the first surface 100a of a substrate 100. The wiring layer 20 may include a plurality of interlayer insulating layers 210 and wiring patterns 211. As a result, a first chip S1 including the photoelectric conversion layer 10 and the wiring layer 20 may be formed.

Thereafter, a second chip S2 may be prepared. The second chip S2 may include a logic substrate 1000, logic circuits TR, wiring structures 1111 connected to the logic circuits TR, and logic interlayer insulating layers 1100. The first chip S1 and the second chip S2 may be bonded to each other. The bonding process may be performed, for example, through a thermal compression bonding process.

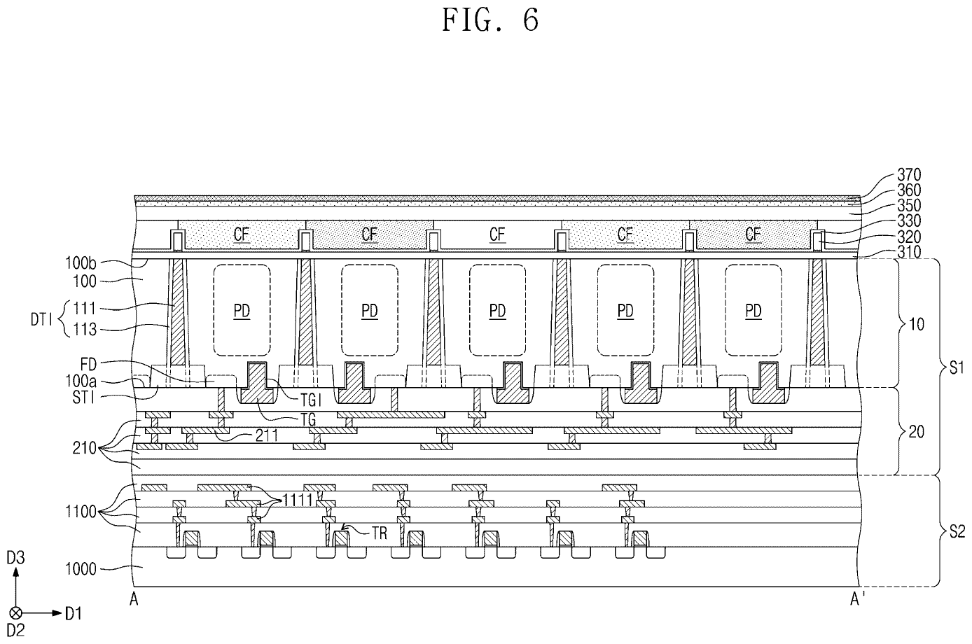

Referring to FIG. 6, a fixed charge layer 310 may be formed on the second surface 100b of the substrate 100. A grid 320 and a first protective layer 330 covering the fixed charge layer 310 and the grid 320 may be formed. A color filter CF and a planarization layer 350 covering the color filter CF may be formed on the fixed charge layer 310. A second protective layer 360 covering the planarization layer 350 may be formed. Thereafter, an etching stop layer 370 may be formed on the second protective layer 360.

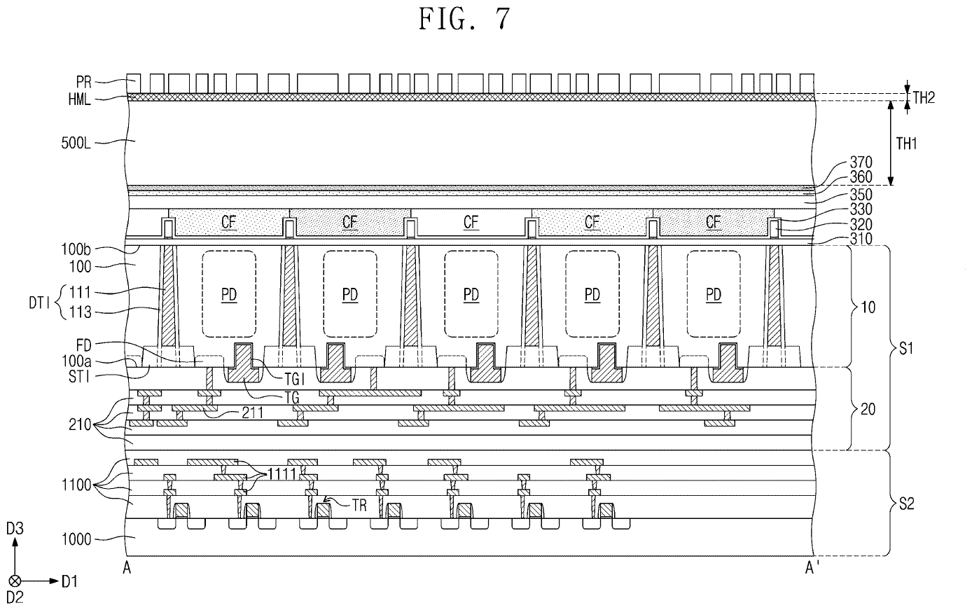

Referring to FIG. 7, a mold layer 500L, a hard mask layer HML, and a photoresist pattern PR may be formed on the etching stop layer 370. The mold layer 500L and the hard mask layer HML may extend in the first direction D1.

A mold layer 500L may have a first thickness TH1 in the third direction D3. The hard mask layer HML may have a second thickness TH2 in the third direction D3. The second thickness TH2 may be less than the first thickness TH1. For example, the second thickness TH2 may be 3% to 10% of the first thickness TH1.

For example, the mold layer 500L may include silicon oxide. The hard mask layer HML may include a material having a high etching selectivity compared to the mold layer 500L. For example, the hard mask layer HML may include at least one of titanium nitride, tantalum nitride, titanium oxide, hafnium oxide, zirconium oxide, tungsten, titanium, tantalum, molybdenum, chromium, hafnium, ruthenium.

As the hard mask layer HML has a high etching selectivity, the thickness of the hard mask layer HML may be reduced while the thickness of the mold layer 500L may be increased to maximize occurrence of a phase difference in light. As a result, light separation phenomenon of the prism structure may be improved.

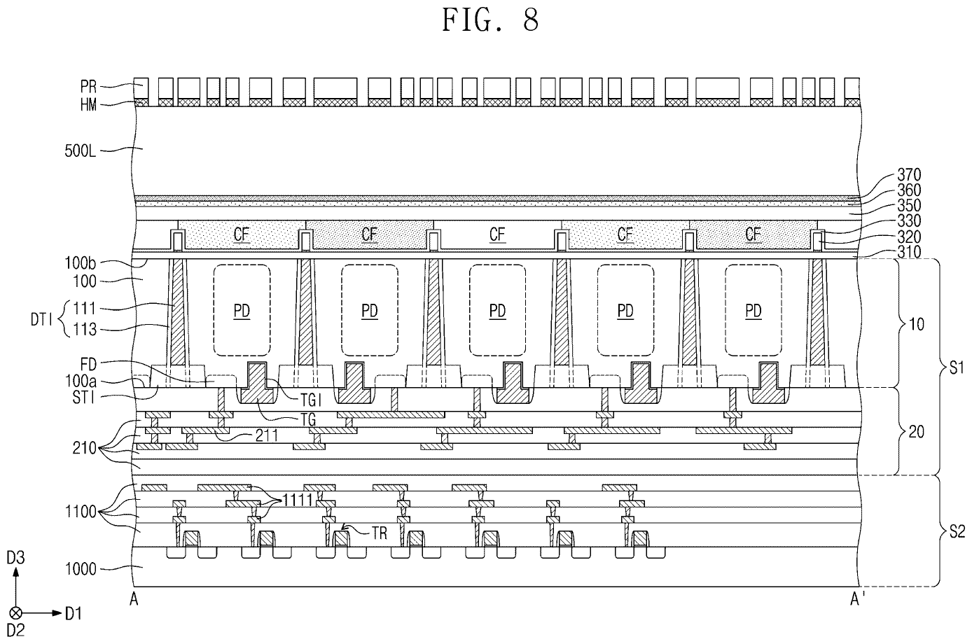

Referring to FIG. 8, the hard mask layer HML may be etched using a photoresist pattern PR as an etching mask. As a result of performing the etching process, a hard mask pattern HM may be formed from the hard mask layer HML. The hard mask pattern HM may define a region where the refractive structure 550 described in FIG. 2 is to be formed.

Referring to FIGS. 9 and 10, an etching process may be performed on the mold layer 500L using the hard mask pattern HM as an etching mask. As a result of the etching process, a mold pattern 500 may be formed from the mold layer 500L. The etching process may be performed, for example, through a dry etching process using ions. The mold pattern 500 may have a plurality of holes H.

In this case, ions used in the dry etching process may collide with the hard mask pattern HM. As a result, the ions may move in a direction other than the vertical direction (e.g., in the diagonal direction) above the mold layer 500L to etch the mold layer 500L, thereby forming the holes H.

Specifically, each of the holes H may include a first hole region H1 and a second hole region H2. The second hole region H2 may be disposed above the first hole region H1. That is, the first hole region H1 may correspond to a lower region of the hole H. The second hole region H2 may correspond to an upper region of the hole H.

A width of the first hole region H1 in the first direction D1 may be constant regardless of a level of the first hole region H1. A width of the second hole region H2 in the first direction D1 may increase in a direction away from the second surface 100b of the substrate 100 and may decrease above a certain level of the second hole region H2. That is, a sidewall H2s of the second hole region H2 may have a shape that is bent inward and the slope may not be constant. This may be a form that appears as the ions collide with the hard mask pattern HM in the dry etching process for the mold layer 500L and move in a direction other than the vertical direction (e.g., in the diagonal direction) to etch the mold layer 500L, as described above.

Referring to FIGS. 11 and 12, a patterning process may be performed on the upper portion of the mold pattern 500, and the width of the second hole region H2 in the first direction D1 may increase in a direction away from the second surface 100b of the substrate 100. The patterning process may be performed, for example, through a chamfering process on the mold pattern 500. As a result of the etching process, the second hole region H2 may have a trapezoidal cross-section, and a slope of the sidewall H2s of the second hole region H2 may be constant. Alternatively, according to some implementations, the sidewall H2s of the second hole region H2 may have a streamlined shape, and the width of the second hole region H2 in the first direction D1 may increase in a direction away from the second surface 100b of the substrate 100.

Referring to FIGS. 13 and 14, a refractive structure 550 that fills the holes H may be formed. The refractive structure 550 may include the same material as the hard mask pattern HM described in FIG. 7. Alternatively, according to some implementations, the refractive structure 550 may include a different material from that of the hard mask pattern HM. The refractive structure 550 may include a high refractive material. The refractive structure 550 may include, for example, at least one of titanium nitride, tantalum nitride, titanium oxide, hafnium oxide, zirconium oxide, tungsten, titanium, tantalum, molybdenum, chromium, hafnium, or ruthenium.

The forming of the refractive structure 550 may be performed through a chemical vapor deposition process and an atomic layer deposition process. In some implementations, as described in the example of FIG. 12, a high refractive material forming the refractive structure 550 may be deposited in the second hole region H2 without generating a void or a seam, as the second hole region H2 has a trapezoidal cross-section. As the refractive structure 550 is formed, the first chip S1 including the light transmitting layer 30 may be completed.

Thereafter, referring to FIGS. 2 and 3, a planarization process may be performed on an upper portion of the mold pattern 500 and an upper portion of the refractive structure 550. As a result of performing the planarization process, a level of an upper surface of the mold pattern 500 and a level of an upper surface of the refractive structure 550 may be lowered. For example, heights of the mold pattern 500 and the refractive structure 550 may be reduced by 0.2 μm to 0.5 μm. As the planarization process is performed, an image sensor according to some implementations may be completed.

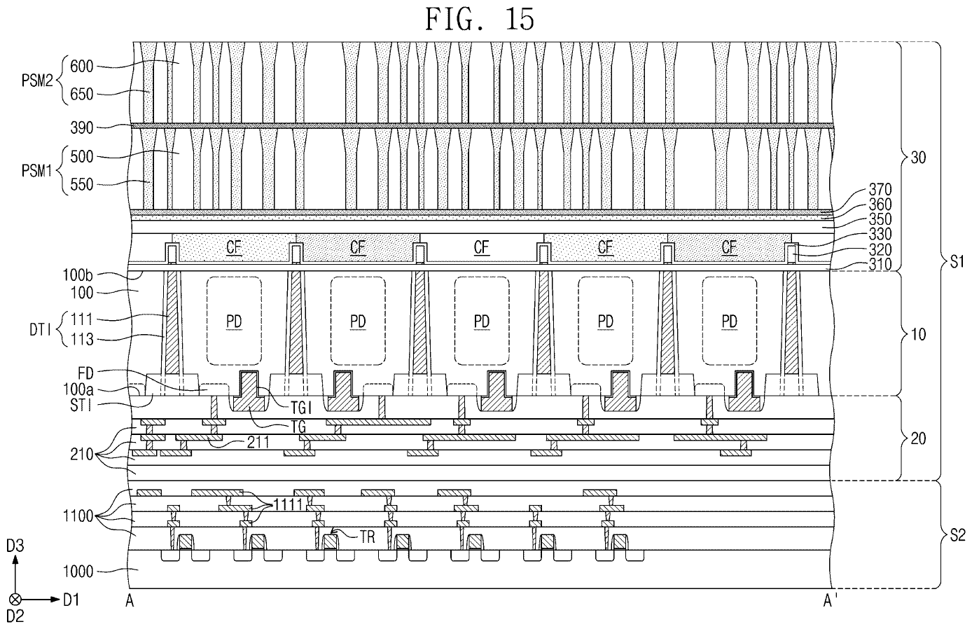

FIG. 15 is a cross-sectional view of an image sensor according to some implementations of the present disclosure. Any description overlapping with FIG. 2 will be omitted.

Referring to FIG. 15, an image sensor according to some implementations of the present disclosure may include a first prism structure PSM1 and a second prism structure PSM2 on the first prism structure PSM1.

The first prism structure PSM1 may correspond to the prism structure PSM described in FIG. 2. The second prism structure PSM2 may include a second mold pattern 600 and a plurality of second refractive structures 650 provided in the second mold pattern 600.

The second mold pattern 600 and the second refractive structures 650 may have shapes substantially similar to the mold pattern 500 and the refractive structure 550 described in FIGS. 2 and 3, respectively. The second mold pattern 600 and the second refractive structures 650 may include materials substantially the same as the mold pattern 500 and the refractive structure 550 described in FIG. 2, respectively. A height of the second mold pattern 600 may be the same as or different from the height of the mold pattern 500.

A second etching stop layer 390 may be disposed between the first prism structure PSM1 and the second prism structure PSM2. The second etching stop layer 390 may include, for example, aluminum oxide.

The number of prism structures provided in the third direction D3 is not limited to that shown, and may be provided in greater numbers. As the plurality of prism structures PSM1 and PSM2 are provided, the phenomenon of color separation of light depending on phase difference may be improved.

The image sensor according to some implementations may include the prism structure on the substrate. The prism structure may include the mold pattern and the refractive structures in the mold pattern and including the high refractive material. In this case, the refractive structure may be formed of the high refractive material without the seam or void, and the width of the upper portion of the refractive structure may increase in the direction away from the substrate. As a result, the light separation phenomenon of the prism structure may be improved, and the image sensor providing the clear image may be provided.

As used herein, the term “at least one of” or “at least one selected from” can refer and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising:
a substrate comprising a plurality of photoelectric convertors; and
a prism structure on the substrate,
wherein the prism structure comprises
a mold pattern, and
a plurality of refractive structures in the mold pattern,
wherein each refractive structure of the plurality of refractive structures comprises a first portion and a second portion, the second portion arranged on the first portion,
wherein the second portion has a first width in a first direction parallel to an upper surface of the substrate, and
wherein the first width increases in a direction away from the upper surface of the substrate.

2. The image sensor of claim 1, wherein the mold pattern comprises silicon oxide, and
wherein the plurality of refractive structures comprise at least one of titanium nitride, tantalum nitride, titanium oxide, hafnium oxide, zirconium oxide, tungsten, titanium, tantalum, molybdenum, chromium, hafnium, or ruthenium.

3. The image sensor of claim 1, wherein the first portion comprises a second width in the first direction, and
wherein the first width is 1.1 to 1.5 times the second width.

4. The image sensor of claim 1, wherein the first portion extends in the direction away from the upper surface of the substrate.

5. The image sensor of claim 1, comprising:
a color filter between the substrate and the prism structure;
a planarization layer on the color filter; and
an etching stop layer on the planarization layer.

6. The image sensor of claim 1, wherein the mold pattern comprises a first height in the direction away from the upper surface of the substrate,
wherein the second portion has a second height in the direction away from the upper surface of the substrate, and
wherein the second height is 10% to 70% of the first height.

7. The image sensor of claim 1, wherein the plurality of refractive structures are in the mold pattern, and
wherein a width of the first portion of each refractive structure of the plurality of refractive structures in the first direction is different.

8. An image sensor comprising:
a substrate comprising a plurality of photoelectric convertors;
a separation structure in the substrate and separating the plurality of photoelectric convertors; and
a prism structure on an upper surface of the substrate,
wherein the prism structure comprises
a mold pattern, and
a plurality of refractive structures in the mold pattern,
wherein each refractive structure of the plurality of refractive structures comprises a first portion and a second portion on the first portion,
wherein an angle between an upper surface of the first portion and a side surface of the second portion is an obtuse angle, and
wherein the second portion comprises a trapezoidal shape when viewed in cross-sectional view.

9. The image sensor of claim 8, wherein the angle between the upper surface of the first portion and the side surface of the second portion is in a range from 91 to 135 degrees.

10. The image sensor of claim 8, wherein the first portion comprises a rectangular shape when viewed in a cross-sectional view.

11. The image sensor of claim 8, wherein a refractive index of the mold pattern is 2.0 or less, and
wherein a refractive index of each refractive structure of the plurality of refractive structures is in a range from 1.2 to 2.5.

12. The image sensor of claim 8, comprising:
a color filter between the substrate and the prism structure;
a planarization layer on the color filter; and
an etching stop layer on the planarization layer.

13. The image sensor of claim 8, wherein the plurality of refractive structures are in the mold pattern, and
wherein a horizontal separation distance between each adjacent pair of refractive structures of the plurality of refractive structures is different.

14. An image sensor comprising:
a substrate comprising a first surface and a second surface facing each other, wherein the substrate comprises a plurality of photoelectric convertors;
a separation structure in the substrate and separating the plurality of photoelectric convertors;
a color filter on the second surface of the substrate; and
a first prism structure on the color filter,
wherein the first prism structure comprises a first mold pattern and a plurality of first refractive structures in the first mold pattern,
wherein a refractive index of each first refractive structure of the plurality of first refractive structures is in a range from 1.2 to 2.5,
wherein each first refractive structure of the plurality of first refractive structures comprises a first portion and a second portion on the first portion,
wherein the first portion comprises a first width in a first direction parallel to the second surface,
wherein the second portion comprises a second width in the first direction,
wherein the first width is constant,
wherein the second width increases in a direction away from the second surface, and
wherein a height of the second portion is 10% to 70% of a height of the first mold pattern.

15. The image sensor of claim 14, comprising a second prism structure on the first prism structure,
wherein the second prism structure comprises a second mold pattern and a plurality of second refractive structures in the second mold pattern.

16. The image sensor of claim 14, wherein a width in the first direction of an upper portion of the first mold pattern between each adjacent pair of first refractive structures decreases along a direction away from the second surface.

17. The image sensor of claim 14, wherein the first mold pattern comprises silicon oxide, and
wherein the plurality of first refractive structures comprise at least one of titanium nitride, tantalum nitride, titanium oxide, hafnium oxide, zirconium oxide, tungsten, titanium, tantalum, molybdenum, chromium, hafnium, or ruthenium.

18. The image sensor of claim 14, wherein the height of the first mold pattern is in range from 0.2 μm to 1.5 μm.

19. The image sensor of claim 14, wherein the second width is 1.1 to 1.5 times the first width.

20. The image sensor of claim 14, wherein an angle between an upper surface of the first portion and a side surface of the second portion is 91 to 135 degrees.
